(19) United States
(12) Patent Application Publication
(10) Pub. No.: US 2025/0261524 A1
(43) Pub. Date: Aug. 14, 2025

(54) DISPLAY DEVICE

(71) Applicant: LG Display Co., Ltd., Seoul (KR)

(72) Inventor: Hanil Kim, Paju-si (KR)

(73) Assignee: LG Display Co., Ltd., Seoul (KR)

(21) Appl. No.: 18/763,164

(22) Filed: Jul. 3, 2024

(30) Foreign Application Priority Data
Feb. 8, 2024 (KR) 10-2024-0019569

(51) Int. Cl. H10K 59/126; H10K 59/121; H10K 59/123; H10K 59/131; H10K 59/40; H10K 59/60; H10K 59/80; H10K 59/88

(52) U.S. Cl. CPC H10K 59/126; H10K 59/1213; H10K 59/123; H10K 59/131; H10K 59/40; H10K 59/60; H10K 59/8731; H10K 59/88

(57) ABSTRACT

A display device can include a substrate including a non-display area including a through hole and a display area surrounding the non-display area, a dam surrounding the through hole, a first hydrogen blocking layer surrounding the dam, a first planarization layer disposed on the first hydrogen blocking layer, a second hydrogen blocking layer surrounding the dam, the second hydrogen blocking layer being disposed on the first planarization layer and overlapping with at least a portion of the first hydrogen blocking layer, and a first contact hole in the first planarization layer, the first contact hole surrounding the dam. Also, the first hydrogen blocking layer is in contact with the second hydrogen blocking layer via the first contact hole.

### CROSS-REFERENCE TO RELATED APPLICATIONS

This application claims priority to Korean Patent Application No. 10-2024-0019569, filed on Feb. 8, 2024, in the Republic of Korea, the entire contents of which are hereby expressly incorporated by reference into the present application.

### BACKGROUND

### Technical Field

The present disclosure relates to a display device, and more particularly, to a display device capable of blocking hydrogen flowing into a transistor.

### Discussion of the Related Art

As information society develops, a demand for display devices that display images is increasing. The display device can be used in various types of devices such as TVs, monitors, tablet computers, navigation, game consoles, and mobile phones, and various types of display devices such as a liquid crystal display (LCD) device and an organic light emitting display (OLED) device are used.

The display device is provided with optical components such as cameras and proximity sensors to provide more diverse functions to users. To recognize light, optical components such as cameras are exposed to the outside. The display device includes a notch or holes formed in a display area (e.g., hole in active area (HIAA)) to expose the optical components. However, the holes formed in a display area may allow hydrogen outgassing to reach the transistor and make the transistor more conductive and damage the transistor. The impaired transistor may cause high brightness defects such as bright spots and abnormal light emission in the display device. Thus, there exists a need for a display device that can block hydrogen flowing into the transistor, improve manufacturing yields and improve quality of the display device.

### SUMMARY OF THE DISCLOSURE

An object of the present disclosure is to provide a display device capable of suppressing a transistor from becoming a conductor by blocking a hydrogen inflow path into the transistor.

Another object of the present disclosure is to provide a display device capable of minimizing a decrease in reliability due to high brightness defects such as strong bright spots and abnormal light emission.

Objects of the present disclosure are not limited to the above-mentioned objects, and other objects, which are not mentioned above, can be clearly understood by those skilled in the art from the following descriptions.

According to an aspect of the present disclosure, a display device includes a substrate including a non-display area including a through hole and a display area surrounding the non-display area, a dam surrounding the through hole, a first hydrogen blocking layer surrounding the dam, a first planarization layer on the first hydrogen blocking layer, a second hydrogen blocking layer surrounding the dam on the first planarization layer overlapping with at least a portion of the first hydrogen blocking layer and a first contact hole surrounding the dam on the first planarization layer, the first hydrogen blocking layer in contact with the second hydrogen blocking layer in the first contact hole.

According to the present disclosure, by disposing a hydrogen blocking layer surrounding the planarization layer exposed by the through hole, it is possible to suppress the penetration of hydrogen diffused from the through hole or the encapsulation part.

According to the present disclosure, it is possible to improve the reliability of the display device by suppressing the oxide semiconductor layer from becoming the conductor due to hydrogen.

According to the present disclosure, it is possible to improve screen defects such as high bright spots and abnormal light emission.

The effects according to the present disclosure are not limited to the contents exemplified above, and further various effects are included in the present disclosure.

The effects of the present disclosure are not limited to the aforementioned effects, and other effects, which are not mentioned above, will be apparently understood to a person having ordinary skill in the art from the following description.

The objects of the present disclosure, the means for achieving the objects, and the effects of the present disclosure described above do not specify essential features of the claims, and, thus, the scope of the claims is not limited to the disclosure of the present disclosure.

### BRIEF DESCRIPTION OF THE DRAWINGS

The above and other aspects, features, and other advantages of the present disclosure will be more clearly understood from the following detailed description taken in conjunction with the accompanying drawings, in which:

FIG. 1 is a schematic plan view of a display device according to an embodiment of the present disclosure;

FIG. 2 is a cross-sectional view taken along line II-II′ of FIG. 1 according to an embodiment of the present disclosure;

FIG. 3 is an enlarged plan view of area A of FIG. 1 according to an embodiment of the present disclosure;

FIG. 4 is a cross-sectional view taken along line IV-IV′ of FIG. 3 according to an embodiment of the present disclosure;

FIG. 5 is a cross-sectional view of a display device according to another embodiment of the present disclosure;

FIG. 6 is a cross-sectional view of a display device according to another embodiment of the present disclosure;

FIG. 7 is a cross-sectional view of a display device according to another embodiment of the present disclosure; and

FIG. 8 is a cross-sectional view of a display device according to another embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of related technologies can be omitted to avoid unnecessarily obscuring the subject matter of the present disclosure. The terms such as “including,” “having,” and “consist of” used herein are generally intended to allow other components to be added unless the terms are used with the term “only.” Any references to singular can include plural unless expressly stated otherwise.

Components are interpreted to include an ordinary error range even if not expressly stated.

When the position relation between two parts is described using the terms such as “on,” “above,” “below,” and “next,” one or more parts can be positioned between the two parts unless the terms are used with the term “immediately” or “directly.”

When an element or layer is disposed “on” another element or layer, another layer or another element can be interposed directly on the other element or therebetween.

Although the terms “first,” “second,” and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, example embodiments of the present disclosure will be described in detail with reference to accompanying drawings.

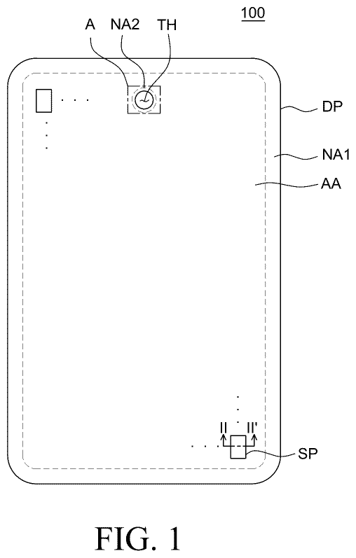

FIG. 1 is a schematic plan view of a display device according to an example embodiment of the present disclosure.

Referring to FIG. 1, a display panel DP of a display device 100 is a panel on which an image is displayed and can have a display element for implementing the image and circuits, lines, components, and the like for driving the display element disposed thereon. The display panel DP can include a display area AA and a non-display area NA. In addition, the non-display area NA can include a through hole TH.

The display area AA can be an area where a plurality of sub-pixels SP are disposed and an image is displayed. Each of the plurality of sub-pixels SP is an individual unit that emits light, and the display element and a driving circuit can be disposed in each of the plurality of sub-pixels SP. For example, the display element for displaying the image and a circuit unit for driving the display element can be disposed in the plurality of sub-pixels SP. In this situation, when the display device 100 is an organic light emitting display device, the display device can include an organic light emitting diode, and when the display device 100 is a liquid crystal display device, the display device can include a liquid crystal device. The plurality of sub-pixels SP can include, but are not limited to, a red sub-pixel, a green sub-pixel, a blue sub-pixel, and a white sub-pixel. The driving circuit can include various transistors, storage capacitors, lines, and the like for driving the plurality of sub-pixels SP. For example, the driving circuit can be composed of various components such as a driving transistor, a switching transistor, a sensing transistor, a storage capacitor, a gate line, and a data line, but is not limited thereto.

The non-display area (NA) is an area where an image is not displayed and can include a first non-display area NA1 and a second non-display area NA2.

The first non-display area NA1 is an area where an image is not displayed and is disposed around the display area AA. The first non-display area NA1 can be an area where various lines, driver ICs, and the like for driving the plurality of sub-pixels SP disposed in the display area AA are disposed. For example, various driving ICs and the like, such as a gate driving IC and a data driving IC, can be disposed in the first non-display area NA1 but are not limited thereto. The first non-display area NA1 where no image is displayed can be a bezel area, and the example embodiments of the present disclosure are not limited thereto.

The second non-display area NA2 is an area where an image is not displayed and is disposed in the display area AA. The second non-display area NA2 can include the through hole TH. In addition, optical sensor components and the like, such as a camera or a proximity sensor, can be disposed in the through hole TH. The second non-display area NA2 can be an area where the through hole TH is disposed within the display area AA and can be defined as a hole in active area (HiAA) area. In addition, the second non-display area NA2 can correspond to the bezel area surrounding the through hole TH.

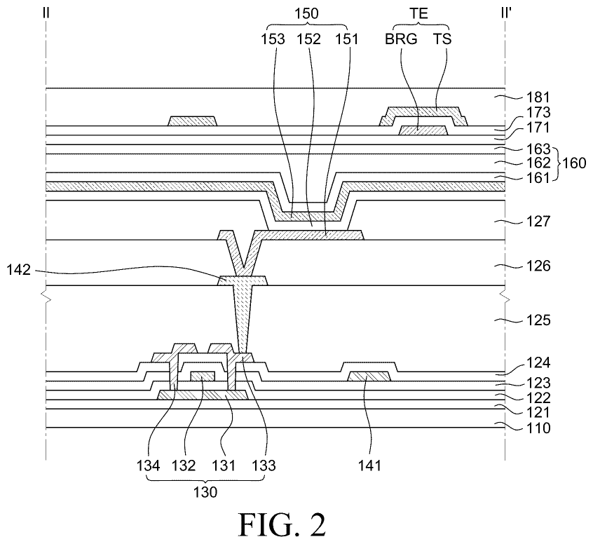

Hereinafter, a specific structure of one sub-pixel SP will be described with reference to FIG. 2.

FIG. 2 is a cross-sectional view taken along line II-II′ of FIG. 1 according to an embodiment of the present disclosure.

Referring to FIGS. 1 and 2, the display device 100 includes a substrate 110, a transistor 130, an auxiliary electrode 141, a connection electrode 142, and a light emitting diode 150.

The substrate 110 is a support member for supporting other components of the display device 100 and can be formed of an insulating material. For example, the substrate 110 can be formed of glass, resin, or the like. In addition, the substrate 110 can be formed of a polymer or plastic such as polyimide (PI) or can be formed of a material with flexibility.

A buffer layer 121 is disposed on the substrate 110. The buffer layer 121 can reduce penetration of moisture or impurities through the substrate 110. In addition, the buffer layer 121 can protect the transistor 130 from impurities such as alkali ions leaking from the substrate 110. In addition, the buffer layer 121 can improve an adhesion between layers formed above the buffer layer 121 and the substrate 110. The buffer layer 121 can be configured by, for example, a single layer or a duplex layer of silicon oxide (SiOx) or silicon nitride (SiNx), but is not limited thereto.

The transistor 130 is disposed on the buffer layer 121. The transistor 130 can drive the light emitting diode 150. The transistor 130 can include an active layer 131, a gate electrode 132, a source electrode 133, and a drain electrode 134.

The active layer 131 is disposed on the buffer layer 121. The active layer 131 is an area where a channel is formed when the transistor 120 is driven. The active layer 131 can include a channel area, a source area, and a drain area. The active layer 131 can be formed of a semiconductor material such as oxide semiconductor, amorphous silicon, or polysilicon, but is not limited thereto.

A gate insulating layer 122 is disposed on the active layer 131. The gate insulating layer 122 is an insulating layer for electrically insulating the active layer 131 and the gate electrode 132. Further, the gate insulating layer 122 can be configured by a single layer or a duplex layer of silicon oxide (SiOx) or silicon nitride (SiNx), but is not limited thereto.

The gate electrode 132 is disposed on the gate insulating layer 122. The gate electrode 132 is disposed on the gate insulating layer 122 to overlap with the channel area of the active layer 131. The gate electrode 132 can be formed of a conductive material, such as copper (Cu), gold (Au), silver (Ag), aluminum (Al), molybdenum (Mo), nickel (Ni), titanium (Ti), chromium (Cr), or an alloy thereof, but is not limited thereto.

A first interlayer insulating layer 123 and a second interlayer insulating layer 124 are disposed on the gate electrode 132. Contact holes are formed in the first interlayer insulating layer 123 and the second interlayer insulating layer 124 to connect the source electrode 133 and the drain electrode 134 to the active layer 131, respectively. The first interlayer insulating layer 123 and the second interlayer insulating layer 124 can be configured by a single layer or a duplex layer of silicon oxide (SiOx) or silicon nitride (SiNx), but are not limited thereto. In addition, the second interlayer insulating layer 124 can be formed of an organic material, and can be configured by a single layer or a duplex layer of, for example, polyimide or photo acryl, but is not limited thereto.

The source electrode 133 and the drain electrode 134 are disposed on the second interlayer insulating layer 124 and spaced apart from each other. The source electrode 133 and the drain electrode 134 are electrically connected to the active layer 131 through the contact holes in the gate insulating layer 122, the first interlayer insulating layer 123, and the second interlayer insulating layer 124.

The source electrode 133 and the drain electrode 134 can be configured by a multi-layer formed of a conductive material, such as copper (Cu), gold (Au), silver (Ag), aluminum (Al), molybdenum (Mo), nickel (Ni), titanium (Ti), chromium (Cr), or an alloy thereof, but is not limited thereto.

For example, the source electrode 133 and the drain electrode 134 can have a three-layer structure. The source electrode 133 and the drain electrode 134 can include a first layer, a second layer disposed on the first layer, and a third layer disposed on the second layer. The first and third layers can be formed of titanium (Ti), and the second layer can be formed of aluminum (Al), but are not limited thereto. Meanwhile, in FIG. 2, for convenience of illustration, the source electrode 133 and the drain electrode 134 are illustrated as a single layer.

The auxiliary electrode 141 is disposed between the first interlayer insulating layer 123 and the second interlayer insulating layer 124. That is, the auxiliary electrode 141 can be disposed on the first interlayer insulating layer 123. The auxiliary electrode 141 can be an electrode forming a storage capacitor or transistors other than the transistor 130 described above, but is not limited thereto. The auxiliary electrode 141 can be formed of a conductive material, such as copper (Cu), gold (Au), silver (Ag), aluminum (Al), molybdenum (Mo), nickel (Ni), titanium (Ti), chromium (Cr), or an alloy thereof, but is not limited thereto.

A first planarization layer 125 and a second planarization layer 126 are disposed on the transistor 130. The first planarization layer 125 and the second planarization layer 126 are insulating layers that planarize an upper portion of the substrate 110. The first planarization layer 125 can include a contact hole for electrically connecting the transistor 130 and the connection electrode 142. Specifically, the first planarization layer 125 can include a contact hole exposing one of the source electrode 133 and the drain electrode 134 of the thin film transistor 130. The second planarization layer 126 can include a contact hole for electrically connecting the connection electrode 142 and the first electrode 151. The first planarization layer 125 and the second planarization layer 126 can be formed of an organic material, and can be configured by a single layer of polyimide or photo acryl or a multi-layer thereof, but is not limited thereto.

The connection electrode 142 is disposed between the first planarization layer 125 and the second planarization layer 126. The connection electrode 142 is an electrode for connecting the source electrode 133 of the transistor 130 and the first electrode 151 of the light emitting diode 150. The connection electrode 142 can be configured by a multi-layer formed of a conductive material, such as copper (Cu), gold (Au), silver (Ag), aluminum (Al), molybdenum (Mo), nickel (Ni), titanium (Ti), chromium (Cr), or an alloy thereof, but is not limited thereto.

For example, the connection electrode 142 can have a three-layer structure. For example, the connection electrode 142 can include a first layer, a second layer disposed on the first layer, and a third layer disposed on the second layer. The first and third layers can be formed of titanium (Ti), and the second layer can be formed of aluminum (Al), but are not limited thereto. Meanwhile, in FIG. 2, the connection electrode 142 is illustrated as a single layer for convenience of illustration.

The light emitting diode 150 is disposed on the second planarization layer 126. The light emitting diode 150 can be disposed in the display area AA. The light emitting diode 150 includes a first electrode 151, a light emitting layer 152, and a second electrode 153. Here, the first electrode 151 can be an anode electrode, and the second electrode 153 can be a cathode electrode.

Meanwhile, the display device 100 can be implemented as a top emission or bottom emission type. In the situation of the top emission type, a reflective layer can be disposed under the first electrode 151 to reflect the light emitted from the light emitting layer 152 to the second electrode 153. For example, the reflective layer can contain a material with excellent reflective properties such as aluminum (Al) or silver (Ag), but is not limited thereto. Conversely, in the situation of the bottom emission type, the first electrode 151 can be made only of a transparent conductive material. Hereinafter, the description will be made assuming that the display device 100 according to an example embodiment of the present disclosure is the top emission type.

The first electrode 151 is disposed on the second planarization layer 126. The first electrode 151 can correspond to each of the plurality of sub-pixels SP. That is, the first electrode 151 can be electrically connected to the connection electrode 142 through the contact hole formed in the second planarization layer 126. In addition, the first electrode 151 can be electrically connected to the source electrode 133 of the transistor 130 through the connection electrode 142. The first electrode 151 can be formed of a conductive material with a high work function in order to supply holes to the light emitting layer 152. For example, the first electrode 151 can be formed of a transparent conductive material such as indium tin oxide (ITO) and indium zinc oxide (IZO), but is not limited thereto.

A bank 127 is disposed on the first electrode 151 and the second planarization layer 126. The bank 127 can be disposed on the second planarization layer 126 to cover an edge of the first electrode 151. The bank 127 is an insulating layer disposed between the plurality of sub-pixels SP to distinguish the plurality of sub-pixels SP. The bank 127 can be an organic insulating material. For example, the bank 127 can be formed of polyimide, acryl, or benzocyclobutene (BCB)-based resin, but is not limited thereto.

The light emitting layer 152 is disposed on the first electrode 151 and the bank 127. The light emitting layer 152 can be disposed over the entire surface of the substrate 110. That is, the light emitting layer 152 can be a common layer commonly disposed in the plurality of sub-pixels SP. The light emitting layer 152 can be an organic layer that emits light of a specific color. For example, the light emitting layer 152 can be one of a red light emitting layer, a green light emitting layer, a blue light emitting layer, and a white light emitting layer. In this situation, when the light emitting layer 152 is composed of the white light emitting layer, a color filter can be further disposed above the light emitting diode 150. The light emitting layer 152 can further include various layers such as a hole transport layer, a hole injection layer, a hole blocking layer, an electron injection layer, an electron blocking layer, and an electron transport layer.

The second electrode 153 is disposed on the light emitting layer 152. The second electrode 153 can be disposed as one layer over the entire surface of the substrate 110. That is, the second electrode 153 can be a common layer commonly disposed in the plurality of sub-pixels SP. The second electrode 153 supplies electrons to the light emitting layer 152, and therefore, can be formed of a conductive material with a low work function. The second electrode 153 can be formed of, for example, transparent conductive material such as indium tin oxide (ITO) and indium zinc oxide (IZO), a metal alloy such as MgAg, a ytterbium (Yb) alloy, or the like and can further contain a metal doping layer, but is not limited thereto.

An encapsulation part 160 is disposed on the light emitting diode 150. The encapsulation part 160 protects the light emitting diode 150 from moisture penetrating from the outside of the display device 100. The encapsulation part 160 includes a first encapsulation layer 161, a foreign matter cover layer 162, and a second encapsulation layer 163.

The first encapsulation layer 161 can be disposed on the second electrode 153 to suppress the penetration of moisture or oxygen. The first encapsulation layer 161 can be formed of an inorganic material such as silicon nitride (SiNx), silicon oxynitride (SiNxOy), or aluminum oxide (AlyOz), but is not limited thereto.

The foreign matter cover layer 162 is disposed on the first encapsulation layer 161 to planarize the surface. In addition, the foreign matter cover layer 162 can cover or block foreign matters or particles that can occur during the manufacturing process. The foreign matter cover layer 162 can be formed of an organic material, for example, silicon oxycarbon (SiOxCz), acrylic, epoxy-based resin, etc. but is not limited thereto.

The second encapsulation layer 163 is disposed on the foreign matter cover layer 162 and can suppress the penetration of moisture or oxygen, like the first encapsulation layer 161. In this situation, the second encapsulation layer 163 and the first encapsulation layer 161 can be disposed to encapsulate the foreign matter cover layer 162. Accordingly, the moisture or oxygen penetrating into the light emitting diode 150 can be more effectively reduced by the second encapsulation layer 163. The second encapsulation layer 163 can be formed of an inorganic material such as silicon oxide (SiOx), silicon nitride (SiNx), silicon oxynitride (SiNxOy), or aluminum oxide (AlyOz), but is not limited thereto.

A touch detection unit can be disposed on the encapsulation part 160. For example, a touch buffer layer 171 can be disposed on the third encapsulation layer 1163, and a touch electrode TE can be disposed on the touch buffer layer 171.

A touch electrode TE can include a touch sensor metal TS and a bridge metal BRG that are located in different layers. A touch interlayer insulating layer 173 can be disposed between the touch sensor metal TS and the bridge metal BRG.

The touch interlayer insulating layer 173 can include an organic material or an inorganic material. In addition, an inorganic layer and an organic layer can be stacked together to form the touch interlayer insulating layer 173.

The touch buffer layer 171 and the touch interlayer insulating layer 173 can be disposed to eliminate a step at a point where the touch electrode TE is disposed and to electrically insulate the touch electrode TE.

A touch planarization layer 181 can be disposed on the touch detection unit. The touch planarization layer 181 can be an organic layer for planarizing and protecting an upper portion of the touch detection unit. For example, the touch planarization layer 181 can be formed of an organic material such as acryl resin, epoxy resin, phenolic resin, polyamide resin, and polyimide resin.

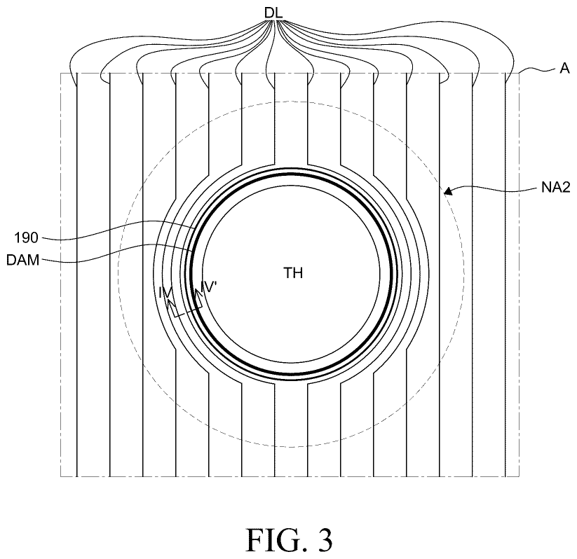

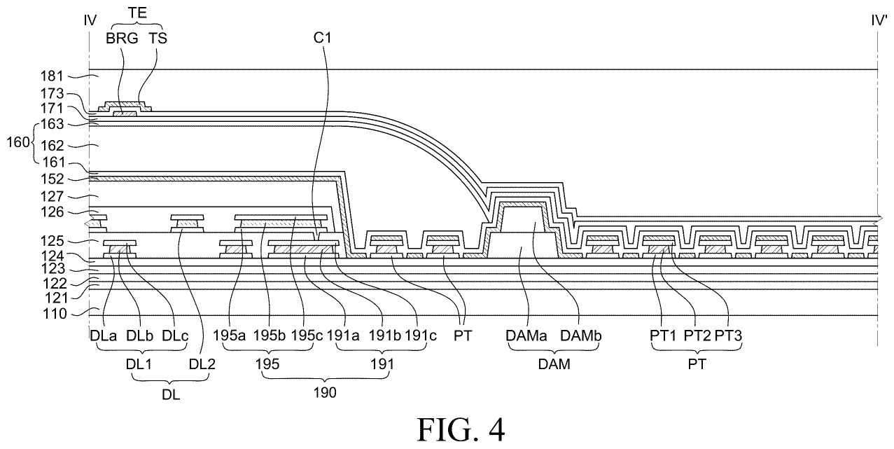

FIG. 3 is an enlarged plan view of area A of FIG. 1, and FIG. 4 is a cross-sectional view taken along line IV-IV′ of FIG. 3 according to an embodiment of the present disclosure. In FIG. 3, for convenience of illustration, only a plurality of data lines DL, a dam DAM, and a hydrogen blocking layer 190 are illustrated among the various components of the display device 100.

Referring to FIGS. 3 and 4, the through hole TH, the dam DAM and a plurality of patterns PT surrounding the through hole TH, a plurality of data lines DL that bypass the hydrogen blocking layer 190 and the through hole TH are disposed in the second non-display area NA2 in the non-display area NA. Here, the second non-display area NA2 can refer to an area in which an image is not displayed among the through hole TH and areas surrounding the through hole TH.

The through hole TH is disposed in the second non-display area NA2. The through hole TH can be disposed to physically penetrate the encapsulation part 160 from the substrate 110. The through hole TH can be disposed to correspond to the camera or the optical sensor. Light can be easily transmitted through the through hole TH from the upper portion of the optical component such as the camera or the optical sensor.

The dam DAM is disposed to surround the through hole TH. The dam DAM can be disposed between the through hole TH and the display area AA. In this situation, the dam DAM can be disposed closer to the through hole TH than the data line DL passing through the second non-display area NA2. Also, the dam DAM can be disposed closer to the through hole TH than the hydrogen blocking layer 190. For example, the dam DAM can fully surround the through hole TH, and the hydrogen blocking layer 190 can fully surround the dam DAM. Also, the hydrogen blocking layer 190 and the dam DAM can have circular shapes or shapes corresponding to the through hole in the plan view, but embodiments are not limited thereto. The dam DAM can suppress the foreign matter cover layer 162, which is part of the encapsulation part 160, from overflowing into the through hole TH. That is, the dam DAM is a structure to suppress the foreign matter cover layer 162 of the encapsulation part 160 for protecting the light emitting diode from penetrating or leaking into the through hole TH. FIGS. 3 and 4 illustrate a single dam DAM, but the number of dams DAM is not limited thereto and can be more than one dam DAM.

The dam DAM can be disposed in a closed curve shape surrounding the outside of the through hole TH. The dam DAM can suppress overflow of the foreign matter cover layer 162. Accordingly, the foreign matter cover layer 162 can be disposed from the display area AA to the inside of the dam DAM.

The dam DAM includes a first sub-dam DAMa and a second sub-dam DAMb on the first sub-dam DAMa. The first sub-dam DAMa can be simultaneously formed of the same material as the second planarization layer 126. The second sub-dam DAMb can be simultaneously formed of the same material as the bank layer 127. However, the material and number of layers of the dam DAM are not limited thereto.

The plurality of patterns PT can be disposed in a closed curve shape surrounding the outside of the through hole TH. The plurality of patterns PT can be disposed between the hydrogen blocking layer 190 and the dam DAM and between the dam DAM and the through hole TH. In addition, the plurality of patterns PT can be disposed to be spaced apart from each other by a certain distance. In FIG. 4, the plurality of patterns PT are illustrated, two on the left and six on the right of the dam (DAM), but are not limited thereto.

The plurality of patterns PT include a first layer PT1, a second layer PT2 disposed on the first layer PT1, and a third layer PT3 disposed on the second layer PT2. The plurality of patterns PT can be disposed on the second interlayer insulating layer 124 and can be formed of the same material and have the same shape as a first hydrogen blocking layer 191 or a second hydrogen blocking layer 195.

The first layer PT1 and the third layer PT3 can contain a titanium (Ti)-based material with excellent hydrogen trapping ability. Titanium (Ti) is a metal with hydrogen adsorption ability which effectively blocks hydrogen. However, the present disclosure is not limited thereto, and the first layer PT1 and the third layer PT3 can contain a titanium (Ti) alloy or titanium dioxide (TiO₂). For example, the first layer PT1 and the third layer PT3 can contain a material such as scandium (Sc), vanadium (V), lead (Pd), niobium (Nb), zirconium (Zr), yttrium (Y), tantalum (Ta), cerium (Ce), lanthanum (La), samarium (Sm), and uranium (U), which have excellent hydrogen adsorption ability, similar to titanium (Ti).

The second layer PT2 can contain a conductive material. For example, the second layer PT2 can contain aluminum (Al), but can be formed of copper (Cu), gold (Au), silver (Ag), molybdenum (Mo), nickel (Ni), titanium (Ti), chromium (Cr), or an alloy thereof, but is not limited thereto.

The plurality of patterns PT can suppress moisture from penetrating into the display area AA through the light emitting layer 152. That is, the light emitting layer 152, which is vulnerable to moisture penetration, can have a single line structure by the plurality of patterns PT. Specifically, the second layer PT2 of the plurality of patterns PT can have a bottom surface smaller than a top surface of the first layer PT1, and the third layer PT3 can have a bottom surface larger than a top surface of the second layer PT2. Accordingly, the light emitting layer 152 disposed on the plurality of patterns PT can be discontinuous and disconnected due to the plurality of patterns PT. For example, a cross-section of each of the plurality of patterns PT can have a mushroom type of shape, an anvil shape or a reverse tapered shape, which can have eaves or overhang portions to form undercut areas, and the plurality of patterns PT cut the light emitting layer 152 to block or prevent potential wicking of moisture into the display area. Accordingly, even if moisture penetrates through the light emitting layer 152 exposed on a side surface of the through hole TH, the penetrated moisture can be suppressed from moving to the display area AA due to the disconnected structure of the light emitting layer 152. In addition, the first encapsulation layer 161 on the light emitting layer 152 can be disposed to completely cover the disconnected light emitting layer 152. Therefore, even if the moisture penetrates through the light emitting layer 152, the first encapsulation layer 161 can effectively block the moisture penetration. While FIG. 4 illustrates only the light emitting layer 152 disposed below the encapsulation part 160, the second electrode 153 can be further disposed between the encapsulation part 160 and the light emitting layer 152.

The plurality of data lines DL can be disposed on the second interlayer insulating layer 124 and the first planarization layer 125. In this situation, the plurality of data lines DL can be disposed closer to the display area AA than the hydrogen blocking layer 190. That is, the plurality of data lines DL can be disposed farther away from the dam DAM and the through hole TH than the hydrogen blocking layer 190. In this situation, the plurality of data lines DL can be disposed between the first hydrogen blocking layer 191, the second hydrogen blocking layer 195 and the transistor 130, and can be disposed to bypass or go around the through hole TH in the second non-display area NA2.

The plurality of data lines DL can include a first data line DL1 disposed on the second interlayer insulating layer 124, and a second data line DL2 disposed on the first planarization layer 125.

The first data line DL1 can be formed of the same material as the source electrode 133, the drain electrode 134, and the first hydrogen blocking layer 191 on the second interlayer insulating layer 124. That is, the first data line DL1 can be formed simultaneously with the source electrode 133, the drain electrode 134, and the first hydrogen blocking layer 191.

The first data line DL1 includes a first layer DLa, a second layer DLb disposed on the first layer DLa, and a third layer DLc disposed on the second layer DLb.

The second layer DLb of the first data line DL1 can have a bottom surface smaller than a top surface of the first layer DLa. In addition, the third layer DLc can have a bottom surface that is larger than a top surface of the second layer DLb. Accordingly, the first data line DL1 can have the first layer DLa and the third layer DLc disposed at the bottom and the top of the first data line DL1, respectively, to have the largest width and the second layer DL1b disposed in the center thereof to have the smallest width. For example, a cross-section of the data lines can have a similar shape as the plurality of patterns PT.

The first layer DLa and the third layer DLc can contain the titanium (Ti)-based material with excellent hydrogen trapping ability. Titanium (Ti) is a metal with hydrogen adsorption ability which effectively blocks hydrogen. However, the present disclosure is not limited thereto, and the first layer and the third layer can contain a titanium (Ti) alloy or titanium dioxide (TiO₂). For example, the first layer DLa and the third layer DLc can contain a material such as scandium (Sc), vanadium (V), lead (Pd), niobium (Nb), zirconium (Zr), yttrium (Y), tantalum (Ta), cerium (Ce), lanthanum (La), samarium (Sm), and uranium (U), which have excellent hydrogen adsorption ability, similar to titanium (Ti).

The second layer DLb can contain a conductive material. For example, the second layer can contain aluminum (Al), but can be formed of copper (Cu), gold (Au), silver (Ag), molybdenum (Mo), nickel (Ni), titanium (Ti), chromium (Cr), or an alloy thereof, but is not limited thereto.

The second data line DL2 can be formed of the same material as the connection electrode 142 and the second hydrogen blocking layer 195 on the first planarization layer 125. The second data line DL2 can be formed simultaneously with the connection electrode 142 and the second hydrogen blocking layer 195.

The second data line DL2 includes a first layer, a second layer disposed on the first layer, and a third layer disposed on the second layer.

The second layer of the second data line DL2 can have the bottom surface smaller than the top surface of the first layer. In addition, the third layer can have the bottom surface larger than the top surface of the second layer. Accordingly, the second data line can have the first and third layers disposed at the bottom and top of the second data line, respectively, to have the largest width and the second layer disposed in the center thereof to have the smallest width.

The first and third layers can contain the titanium (Ti)-based material with excellent hydrogen trapping ability. Titanium (Ti) is metal with hydrogen adsorption ability which effectively blocks hydrogen. However, the present disclosure is not limited thereto, and the first layer and the third layer can contain a titanium (Ti) alloy or titanium dioxide (TiO₂). For example, the first layer and the third layer can contain a material such as scandium (Sc), vanadium (V), lead (Pd), niobium (Nb), zirconium (Zr), yttrium (Y), tantalum (Ta), cerium (Ce), lanthanum (La), samarium (Sm), and uranium (U), which have excellent hydrogen adsorption ability, similar to titanium (Ti).

The second layer can include a conductive material. For example, the second layer can contain aluminum (Al), but can be formed of copper (Cu), gold (Au), silver (Ag), molybdenum (Mo), nickel (Ni), titanium (Ti), chromium (Cr), or an alloy thereof, but is not limited thereto.

The hydrogen blocking layer 190 is disposed to surround the dam DAM. The hydrogen blocking layer 190 can be disposed between the dam DAM and the display area AA. In this situation, the hydrogen blocking layer 190 can be disposed closer to the plurality of data lines DL passing through the second non-display area NA2 than the dam DAM. The hydrogen blocking layer 190 can be disposed in a closed loop shape to surround the dam DAM centered on the through hole TH.

The hydrogen blocking layer 190 can include the first hydrogen blocking layer 191 and the second hydrogen blocking layer 195.

The first hydrogen blocking layer 191 can be disposed on the second interlayer insulating layer 124. The first hydrogen blocking layer 191 can be disposed on the second interlayer insulating layer 124 and can be formed of the same material as the source electrode 133, the drain electrode 134, and the first data line DL. The first hydrogen blocking layer 191 can contain titanium (Ti). That is, the first hydrogen blocking layer 191 can be formed simultaneously with the source electrode 133, the drain electrode 134, and the first data line DL.

The first hydrogen blocking layer 191 can include a first layer 191a, a second layer 191b disposed on the first layer 191a, and a third layer 191c disposed on the second layer 191b.

The second layer 191b of the first hydrogen blocking layer 191 can have a bottom surface smaller than a top surface of the first layer 191a. In addition, the third layer 191c can have a bottom surface larger than a top surface of the second layer 191b. Accordingly, the first hydrogen blocking layer 191 can have the first layer 191a and the third layer 191c disposed at the bottom and the top of the first hydrogen blocking layer 191, respectively, to have the largest width and the second layer 191b disposed in the center thereof to have the smallest width.

The first layer 191a and the third layer 191c can contain the titanium (Ti)-based material with excellent hydrogen trapping ability. Titanium (Ti) is a metal with hydrogen adsorption ability which effectively blocks hydrogen. However, the present disclosure is not limited thereto, and the first layer 191a and the third layer 191c can contain a titanium (Ti) alloy or titanium dioxide (TiO₂). For example, the first layer 191a and the third layer 191c can contain a material such as scandium (Sc), vanadium (V), lead (Pd), niobium (Nb), zirconium (Zr), yttrium (Y), tantalum (Ta), cerium (Ce), lanthanum (La), samarium (Sm), and uranium (U), which have excellent hydrogen adsorption ability, similar to titanium (Ti).

The second layer 191b can contain a conductive material. For example, the second layer can contain aluminum (Al), but can be formed of copper (Cu), gold (Au), silver (Ag), molybdenum (Mo), nickel (Ni), titanium (Ti), chromium (Cr), or an alloy thereof, but is not limited thereto.

Meanwhile, the first planarization layer 125 is disposed on the second interlayer insulating layer 124, the plurality of data lines DL, and the first hydrogen blocking layer 191.

The second hydrogen blocking layer 195 can be disposed to overlap with the first hydrogen blocking layer 191 on the first planarization layer 125. The second hydrogen blocking layer 195 can be disposed in a first contact hole C1 of the first planarization layer 125 to be in contact with the first hydrogen blocking layer 191.

The second hydrogen blocking layer 195 can be formed of the same material as the connection electrode 142. The second hydrogen blocking layer 195 can contain titanium (Ti). The second hydrogen blocking layer 195 can be formed simultaneously with the connection electrode 142 on the first planarization layer 125.

The second hydrogen blocking layer 195 can include a first layer 195a, a second layer 195b disposed on the first layer 195a, and a third layer 195c disposed on the second layer 195b.

The second layer 195b of the second hydrogen blocking layer 195 can have a bottom surface smaller than a top surface of the first layer 195a. In addition, the third layer 195c can have a bottom surface larger than a top surface of the second layer 195b. Accordingly, the second hydrogen blocking layer 195 can have the first layer 195a and the third layer 195c disposed at the bottom and the top of the second hydrogen blocking layer 195, respectively, to have the largest width and the second layer 195b disposed in the center thereof to have the smallest width.

The first layer 195a and the third layer 195c can contain the titanium (Ti)-based material with excellent hydrogen trapping ability. Titanium (Ti) is a metal with hydrogen adsorption ability which effectively blocks hydrogen. However, the present disclosure is not limited thereto, and the first layer 195a and the third layer 195c can contain a titanium (Ti) alloy or titanium dioxide (TiO₂). For example, the first layer 195a and the third layer 195c can contain a material such as scandium (Sc), vanadium (V), lead (Pd), niobium (Nb), zirconium (Zr), yttrium (Y), tantalum (Ta), cerium (Ce), lanthanum (La), samarium (Sm), and uranium (U), which have excellent hydrogen adsorption ability, in addition to titanium (Ti).

The second layer 195b can contain a conductive material. For example, the second layer 195b can contain aluminum (Al), but can be formed of copper (Cu), gold (Au), silver (Ag), molybdenum (Mo), nickel (Ni), titanium (Ti), chromium (Cr), or an alloy thereof, but is not limited thereto.

The hydrogen blocking layer 190 can be electrically floated. Specifically, the first hydrogen blocking layer 191 and the second hydrogen blocking layer 195 can electrically float. That is, a voltage is not applied to the hydrogen blocking layer 190, and the hydrogen blocking layer 190 can be maintained in an electrically floating state. For example, the hydrogen blocking layer 190 can include a plurality of dummy data lines (e.g., hydrogen blocking layers) that fully circle around the through hole TH, and the plurality of dummy data lines can be interconnected with each other forming a mesh type blocking structure, a bird's nest type of structure or a multi-layered walled structure, but embodiments are not limited thereto. Accordingly, together, the plurality of dummy data lines (e.g., hydrogen blocking layers) can form a combined structure that can better prevent hydrogen or other gasses that may enter through the through hole TH from reaching the transistors in the display area AA. Thus, the transistors in the display area AA can be securely protected.

The hydrogen blocking layer 190 can block a path through which hydrogen flows into the transistor 130 through the first planarization layer 125. That is, the hydrogen blocking layer 190 can have the hydrogen blocking structure that blocks the path through which the hydrogen diffused from the inside of the encapsulation part 160 or the through hole TH flows through the side surface of the first planarization layer 125. Specifically, the hydrogen blocking layer 190 is formed of a material with excellent hydrogen trapping ability as described above, and can be disposed to completely cover the side surface of the first planarization layer 125 by the second hydrogen blocking layer 195 connected to the first hydrogen blocking layer 191 through the first contact hole C1. For example, the first contact hole C1 extends from bottom surface of the second hydrogen blocking layer 195 to the upper surface of the first hydrogen blocking layer 191 to block the space between the first and second hydrogen blocking layers in the first planarization layer 125. In addition, the hydrogen blocking layer 190 is disposed in a closed loop shape to surround the dam DAM with the through hole TH in the center. Accordingly, even if hydrogen diffuses from the encapsulation part 160 or the through hole TH, the hydrogen blocking structure of the hydrogen blocking layer 190 can suppress or prevent the hydrogen from flowing into the transistor 130 in the display area AA.

Generally, in order to dispose the optical components such as the camera in the display area, a through hole is disposed in the display area, and the optical components such as a camera are disposed in an area corresponding to the through hole. When the through hole is disposed in the display area, the hydrogen diffusing from the encapsulation part can penetrate into the planarization layer through a side surface portion of the planarization layer. In addition, when the hydrogen that penetrates in this way reaches an active layer of the transistor, the transistor may become conductive. The conductive transistor may cause high brightness defects such as highly bright spots and abnormal light emission may occur in the display device due to the transistor being the conductor.

Accordingly, in the display device 100 according to the example embodiment of the present disclosure, the hydrogen blocking layer 190 can be disposed to cover the side surface of the first planarization layer 125, thereby blocking a hydrogen inflow path. Specifically, the hydrogen blocking layer 190 can be disposed to completely cover the side surface of the first planarization layer 125 by the first contact hole C1 connecting the second hydrogen blocking layer 195 to the first hydrogen blocking layer 191. The hydrogen blocking layer 190 blocks the path through which the hydrogen diffusing from the encapsulation part 160 may penetrate into the first planarization layer 125. In addition, the hydrogen blocking layer 190 can be disposed in a closed loop shape to surround the dam DAM with the through hole TH in the center, and thus, can suppress the hydrogen from flowing into the transistor 130 in the display area AA even if the hydrogen diffuses from the encapsulation part 160 or the through hole TH. Accordingly, in the display device 100 according to the example embodiment of the present disclosure, the hydrogen blocking layer 190 can suppress an oxide semiconductor layer from becoming the conductor due to the hydrogen, and improve the reliability of the display device 100. Therefore, in the display device 100 according to the example embodiment of the present disclosure, by suppressing the transistor 130 from becoming the conductor due to the hydrogen, the high brightness defects such as the strong bright spots and abnormal light emission can be minimized or prevented.

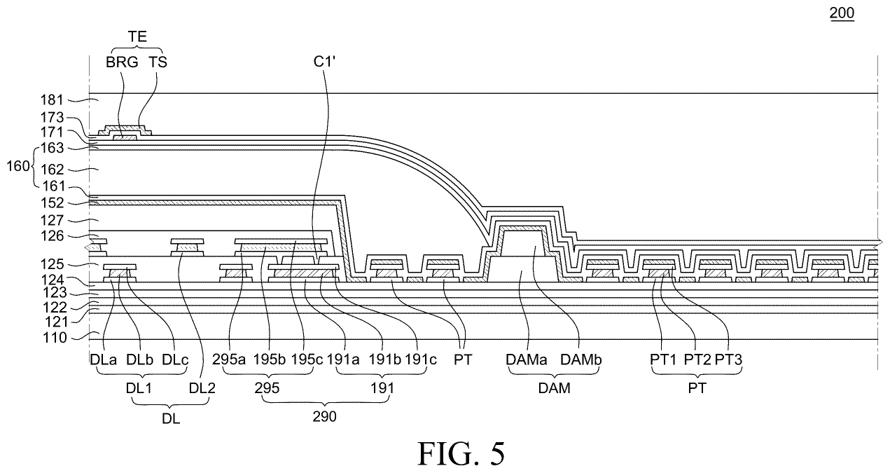

FIG. 5 is a cross-sectional view of a display device according to another example embodiment of the present disclosure. The display device 200 of FIG. 5 is different than the display device 100 of FIGS. 1 to 4 with respect to a hydrogen blocking layer 290, and other components are substantially the same, so duplicate descriptions thereof will be omitted.

Referring to FIG. 5, the hydrogen blocking layer 290 can include a second hydrogen blocking layer 295 disposed to overlap with the first hydrogen blocking layer 191. For example, the hydrogen blocking layer 290 can include a plurality of stacked dummy data lines that fully encircle or form rings around the through hole TH. In this situation, the second hydrogen blocking layer 295 can be in contact with the first hydrogen blocking layer 191 through a first contact hole C1′ of the first planarization layer 125. Here, there can be more than one of first contact hole C1′. For example, a plurality of dummy data lines (e.g., hydrogen blocking layers) can be stacked on top of each other and connected to teach other through multiple contact holes forming a combined walled structure having a ring shape that can fully protect the side of the first planarization layer 125. That is, a first layer 295a of the second hydrogen blocking layer 295 can be in contact with the first hydrogen blocking layer 191 through the plurality of first contact holes C1′ penetrating through the first planarization layer 125. Accordingly, the second hydrogen blocking layer 295 can be in contact with the first hydrogen blocking layer 191 via the plurality of contact holes C1′ of the first planarization layer 125 to completely cover the side surface of the first planarization layer 125. In FIG. 5, the number of the plurality of first contact holes C1′ is illustrated as two, but is not limited thereto.

Accordingly, in the display device 200 according to another example embodiment of the present disclosure, the hydrogen blocking layer 290 can be disposed to cover the side surface of the first planarization layer 125, thereby blocking a hydrogen inflow path. Specifically, the hydrogen blocking layer 190 can be disposed to completely cover the side surface of the first planarization layer 125 by the second hydrogen blocking layer 195 connected to the first hydrogen blocking layer 191 through the first contact holes C1′. The hydrogen blocking layer 190 blocks the path through which the hydrogen diffusing from the encapsulation part 160 may penetrate into the first planarization layer 125 through the side surface portion of the first planarization layer 125. The hydrogen blocking layer 190 can suppress or prevent the hydrogen from flowing into the transistor 130 in the display area AA even if the hydrogen diffuses from the through hole TH.

In addition, in the display device 200 according to another example embodiment of the present disclosure, by having the plurality of first contact holes C1′ of the first planarization layer 125 connecting the first hydrogen blocking layer 191 and the second hydrogen blocking layer 295 with each other, the hydrogen blocking layer 290 can stably block the hydrogen inflow path even if some of the plurality of first contact holes C1′ are disconnected. That is, when the first contact hole C1 configured to cover the side surface of the first planarization layer 125 is disconnected due to the impact, the side surface of the first planarization layer 125 may be exposed. In this situation, the plurality of first contact holes C1′ connecting the second hydrogen blocking layer 295 to the first hydrogen blocking layer 191 can more stably block the path through which the hydrogen diffusing from the encapsulation part 160 through the side surface portion of the first planarization layer 125 penetrates into the first planarization layer 125. Accordingly, in the display device 200 according to another example embodiment of the present disclosure, by disposing the hydrogen blocking layer 290 including the plurality of first contact holes C1′ connecting the first hydrogen blocking layer 191 and the second hydrogen blocking layer 295, it is possible to more stably block the hydrogen inflow path. For example, a multi-layered walled structure can be provided. Also, the contact holes can extend all the way around the through hole TH in a closed ring shape that corresponds to the hydrogen blocking layers, but embodiments are not limited thereto. By suppressing the oxide semiconductor layer, which is the active layer 131 of the transistor 130, from becoming the conductor due to the hydrogen, the hydrogen blocking layer 290 can improve the reliability of the display device 200.

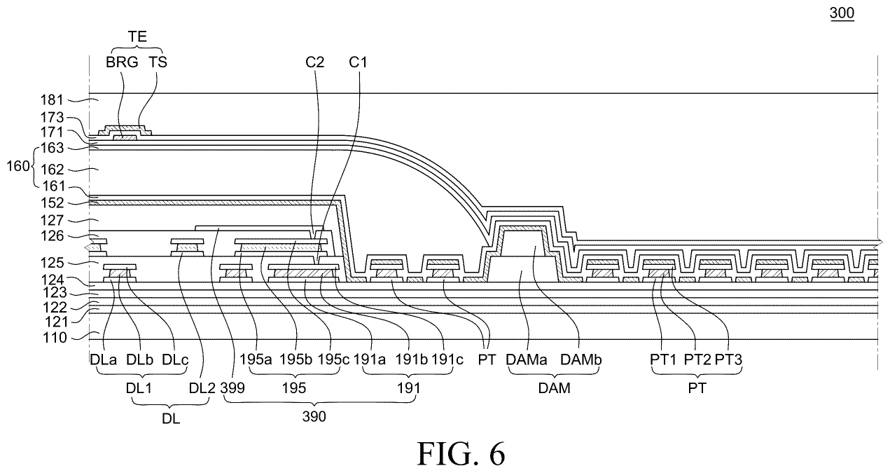

FIG. 6 is a cross-sectional view of a display device according to another example embodiment of the present disclosure. The display device 200 of FIG. 6 is different than the display device 100 of FIGS. 1 to 4 only in a hydrogen blocking layer 390 (e.g., a third hydrogen blocking layer 399 is further included), and other components are substantially the same, so duplicate descriptions thereof will be omitted.

Referring to FIG. 6, the hydrogen blocking layer 390 can include the first hydrogen blocking layer 191, the second hydrogen blocking layer 195, and a third hydrogen blocking layer 399.

The third hydrogen blocking layer 399 can be disposed on the second hydrogen blocking layer 195. Specifically, the third hydrogen blocking layer can be disposed to overlap with the second hydrogen blocking layer 195 on the second planarization layer 126. The third hydrogen blocking layer 399 can be in contact with the second hydrogen blocking layer 195 through the second contact hole C2 of the second planarization layer 126. For example, the hydrogen blocking layer 390 can have a triple layer walled structure that covers the sides of both of first planarization layer 125 and the second planarization layer 126, and an upper surface of second planarization layer 126.

The third hydrogen blocking layer 399 can include the titanium (Ti)-based material with excellent hydrogen trapping ability. Titanium (Ti) is a metal with hydrogen adsorption ability which effectively blocks hydrogen. However, the present disclosure is not limited thereto, and the third hydrogen blocking layer 399 can contain titanium (Ti) alloy or titanium dioxide (TiO₂). For example, the third hydrogen blocking layer 399 can contain a material such as scandium (Sc), vanadium (V), lead (Pd), niobium (Nb), zirconium (Zr), yttrium (Y), tantalum (Ta), cerium (Ce), lanthanum (La), samarium (Sm), and uranium (U), which have excellent hydrogen adsorption ability, similar to titanium (Ti).

The hydrogen blocking layer 390 can be electrically floated. Specifically, the first hydrogen blocking layer 191, the second hydrogen blocking layer 195, and the third hydrogen blocking layer 399 can electrically float. That is, a voltage is not applied to the hydrogen blocking layer 390, and the hydrogen blocking layer 390 can be maintained in an electrically floating state.

The hydrogen blocking layer 390 can block the path through which the hydrogen flows into the transistor 130 through the first planarization layer 125 and the second planarization layer 126. That is, the hydrogen blocking layer 390 can have the hydrogen blocking structure that blocks the path through which the hydrogen diffused from the inside of the encapsulation part 160 or the through hole TH flows through the side surfaces of the first planarization layer 125 and the second planarization layer 126. Specifically, the hydrogen blocking layer 390 is formed of a material with excellent hydrogen trapping ability as described above. The hydrogen blocking layer 390 can be disposed to completely cover the side surface of the first planarization layer 125 by the second hydrogen blocking layer 195 connected to the first hydrogen blocking layer 191 through the first contact hole C1. Also, the hydrogen blocking layer 390 can be disposed to completely cover the side surface of the second planarization layer 126 by the third hydrogen blocking layer 399 connected to the second hydrogen blocking layer 195 through the second contact hole C2. For example, the second contact hole C2 extends from bottom surface of the third hydrogen blocking layer 399 to the upper surface of the second hydrogen blocking layer 195 to block the space between the second and third hydrogen blocking layer in the second planarization layer 126. In addition, the hydrogen blocking layer 390 is disposed in a closed loop shape to surround the dam DAM with the through hole TH in the center. Also, the contact holes can be formed in a closed loop shape or ring shape and filled with metal to fully seal the sides of the planarization layers, but embodiments are not limited thereto. Accordingly, even if hydrogen diffuses from the encapsulation part 160 or the through hole TH, the hydrogen blocking structure of the hydrogen blocking layer 190 can suppress or prevent the hydrogen from flowing into the transistor 130 in the display area AA.

Accordingly, in a display device 300 according to still another example embodiment of the present disclosure, the hydrogen blocking layer 390 can be disposed to cover the side surfaces of the first planarization layer 125 and the second planarization layer 126, thereby blocking the hydrogen inflow path. Specifically, the hydrogen blocking layer 390 can be disposed to completely cover the side surface of the first planarization layer 125 by the second hydrogen blocking layer 195 connected to the first hydrogen blocking layer 191 through the first contact hole C1. Also, the hydrogen blocking layer 390 can be disposed to completely cover the side surface of the second planarization layer 126 by the third hydrogen blocking layer 399 connected to the second hydrogen blocking layer 195 through the second contact hole C2. Therefore, the hydrogen blocking layer 390 can block the path through which the hydrogen diffused from the encapsulation part 160 through the side surface portions of the first planarization layer 125 and the second planarization layer 126 may penetrate into the first planarization layer 125 and the second planarization layer 126. Accordingly, in the display device 300 according to still another example embodiment of the present disclosure, the hydrogen blocking layer 390 can be disposed to suppress or prevent the transistor 130 from becoming the conductor due to the hydrogen, thereby minimizing the high brightness defects such as the strong bright spots and abnormal light emission and improving the reliability of the display device 300.

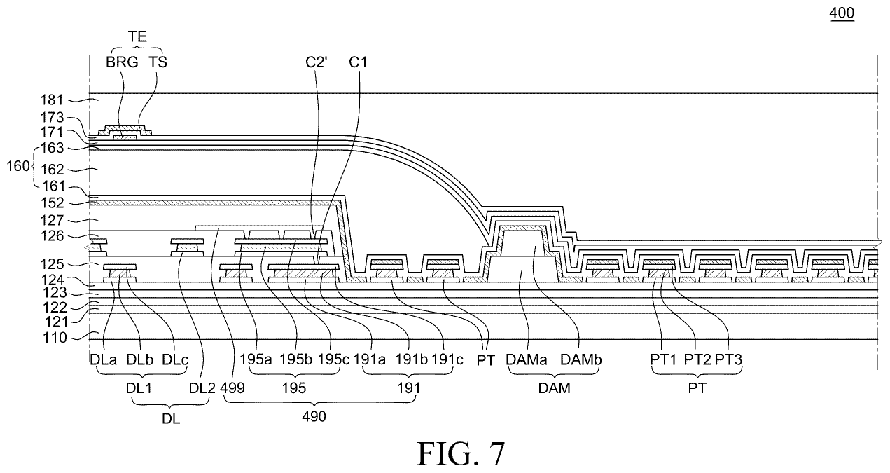

FIG. 7 is a cross-sectional view of a display device according to another example embodiment of the present disclosure. A display device 400 of FIG. 7 is different than the display device 300 of FIG. 6 with respect to a hydrogen blocking layer 490, and other components are substantially the same, so duplicate descriptions thereof will be omitted.

Referring to FIG. 7, the hydrogen blocking layer 490 can include the first hydrogen blocking layer 191, the second hydrogen blocking layer 195, and a third hydrogen blocking layer 499.

The hydrogen blocking layer 490 includes the third hydrogen blocking layer 499 disposed to overlap with the second hydrogen blocking layer 195. In this situation, the third hydrogen blocking layer 499 can be in contact with the second hydrogen blocking layer 195 through the second contact hole C2′ of the second planarization layer 126. Here, there can be more than one of second contact hole C2′. For example, the third hydrogen blocking layer 499 can be connected to the second hydrogen blocking layer 195 via three or more contacts holes. Also, the contact holes can be formed in a closed loop shape or ring shape and filled with metal to fully seal the sides of the planarization layers, but embodiments are not limited thereto. That is, the third hydrogen blocking layer 499 can be in contact with the second hydrogen blocking layer 195 through the plurality of second contact holes C2′ penetrating through the second planarization layer 126. Accordingly, the third hydrogen blocking layer 499 can be in contact with the second hydrogen blocking layer 195 by the plurality of contact holes C2′ of the second planarization layer 126 to completely cover the side surface of the second planarization layer 126. In FIG. 7, the number of second contact holes C2′ is illustrated as three, but is not limited thereto.

The third hydrogen blocking layer 499 can include the titanium (Ti)-based material with excellent hydrogen trapping ability. Titanium (Ti) a metal with hydrogen adsorption ability which effectively blocks hydrogen. However, the present disclosure is not limited thereto, and the third hydrogen blocking layer 499 can contain titanium (Ti) alloy or titanium dioxide (TiO₂). For example, the third hydrogen blocking layer 399 can contain a material such as scandium (Sc), vanadium (V), lead (Pd), niobium (Nb), zirconium (Zr), yttrium (Y), tantalum (Ta), cerium (Ce), lanthanum (La), samarium (Sm), and uranium (U), which have excellent hydrogen adsorption ability, similar to titanium (Ti).

Accordingly, in a display device 400 according to still another example embodiment of the present disclosure, the hydrogen blocking layer 490 can be disposed to cover the side surfaces of the first planarization layer 125 and the second planarization layer 126, thereby blocking the hydrogen inflow path. Specifically, the hydrogen blocking layer 490 can be disposed to completely cover the side surface of the first planarization layer 125 by the second hydrogen blocking layer 195 connected to the first hydrogen blocking layer 191 through the first contact hole C1. Also, the hydrogen blocking layer 490 can be disposed to completely cover the side surface of the second planarization layer 126 by the third hydrogen blocking layer 499 connected to the second hydrogen blocking layer 195 through the plurality of second contact holes C2′. Therefore, the hydrogen blocking layer 490 can block the path through which the hydrogen diffused from the encapsulation part 160 through the side surface portions of the first planarization layer 125 and the second planarization layer 126 may penetrate into the first planarization layer 125 and the second planarization layer 126.

In addition, in the display device 400 according to still another example embodiment of the present disclosure, by the plurality of second contact holes C2′ of the second planarization layer 126 connecting the second hydrogen blocking layer 195 and the third hydrogen blocking layer 499 the hydrogen blocking layer 490 can stably block the hydrogen inflow path even if some of the plurality of second contact holes C2′ are disconnected. That is, when the second contact hole C2 configured to cover the side surface of the second planarization layer 126 is disconnected due to the impact, the side surface of the second planarization layer 126 may be exposed. In this situation, the plurality of second contact holes C2′ connecting the third hydrogen blocking layer 499 to the second hydrogen blocking layer 195 can more stably block the path through which the hydrogen diffusing from the encapsulation part 160 through the side surface portion of the second planarization layer 126 penetrates into the second planarization layer 126 (e.g., the plurality of contact holes can be filled with metal and act as back up walls, in case one of the contact holes become compromised). Accordingly, in the display device 400 according to still another example embodiment of the present disclosure, the hydrogen blocking layer 490 can be disposed to suppress the transistor 130 from becoming the conductor due to the hydrogen, thereby minimizing the high brightness defects such as the strong bright spots and abnormal light emission and improving the reliability of the display device 400.

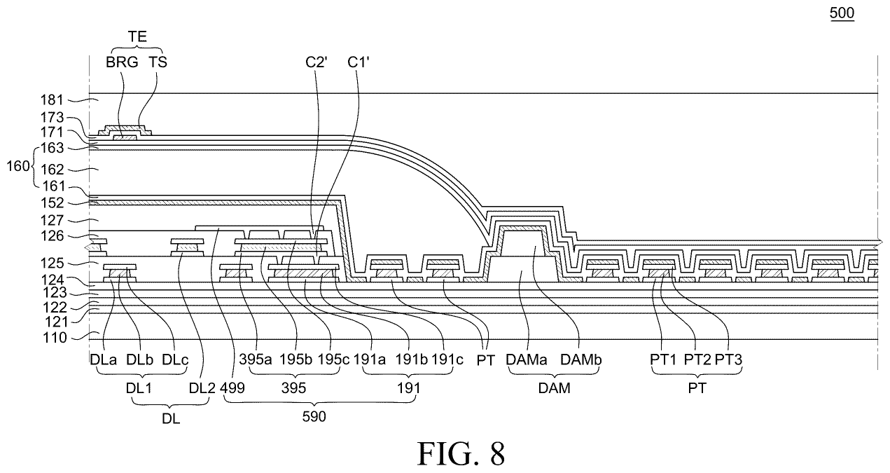

FIG. 8 is a cross-sectional view of a display device according to still another example embodiment of the present disclosure. A display device 500 of FIG. 8 is different than the display device 400 of FIG. 7 with respect to a hydrogen blocking layer 590, and other components are substantially the same, so duplicate descriptions thereof will be omitted.

Referring to FIG. 8, the hydrogen blocking layer 590 can include the first hydrogen blocking layer 191, a second hydrogen blocking layer 395, and a third hydrogen blocking layer 499.

The second hydrogen blocking layer 395 can be in contact with the first hydrogen blocking layer 191 through the first contact hole C1′ of the first planarization layer 125. Here, there can be more than one of first contact holes C1′. That is, a first layer 395a of the second hydrogen blocking layer 395 can be in contact with the first hydrogen blocking layer 191 through the plurality of first contact holes C1′ penetrating through the first planarization layer 125. Accordingly, the second hydrogen blocking layer 395 can be in contact with the first hydrogen blocking layer 191 by the plurality of contact holes C1′ of the first planarization layer 125 to completely cover the side surface of the first planarization layer 125. In FIG. 8, the number of the plurality of first contact holes C1′ is illustrated as two, but is not limited thereto.

Accordingly, in the display device 500 according to another example embodiment of the present disclosure, the hydrogen blocking layer 590 can be disposed to cover the side surfaces of the first planarization layer 125 and the second planarization layer 126, thereby blocking the hydrogen inflow path. Specifically, the hydrogen blocking layer 590 can be disposed to completely cover the side surface of the first planarization layer 125 by the second hydrogen blocking layer 395 connected to the first hydrogen blocking layer 191 through the plurality of first contact holes C1′. Also, the hydrogen blocking layer 590 can be disposed to completely cover the side surface of the second planarization layer 126 by the third hydrogen blocking layer 499 connected to the second hydrogen blocking layer 395 through the plurality of second contact holes C2′. In FIG. 8, the number of the plurality of second contact holes C2′ is illustrated as three, but is not limited thereto. The number of second contact holes C2′ can be greater than the number of first contact holes C1′. For example, in FIG. 8, the number of second contact holes C2′ is three and the number of first contact holes C1′ is two, but is not limited thereto.

Therefore, the hydrogen blocking layer 590 can block the path through which the hydrogen diffused from the encapsulation part 160 through the side surface portions of the first planarization layer 125 and the second planarization layer 126 may penetrate into the first planarization layer 125 and the second planarization layer 126.

In addition, in the display device 500 according to another example embodiment of the present disclosure, the plurality of first contact holes C1′ of the first planarization layer 125 can connect the first hydrogen blocking layer 191 and the second hydrogen blocking layer 395 and the plurality of second contact holes C2′ of the second planarization layer 126 can connect the second hydrogen blocking layer 395 and the third hydrogen blocking layer 499. In this way, the contact holes can be filled with metal to form a large, multi-layered walled structure having a closed loop shape or ring shape that surrounds the through hole TH. Thus, even if at least one of the plurality of first contact holes C1′ and the plurality of second contact holes C2′ is disconnected, the hydrogen blocking layer 590 can more stably block the path through which the hydrogen diffusing from the encapsulation part 160 through the side surface portions of the first planarization layer 125 and the second planarization layer 126 penetrates into the first planarization layer 125 and the second planarization layer 126. Accordingly, in the display device 500 according to another example embodiment of the present disclosure, the hydrogen blocking layer 590 can be disposed to suppress the transistor 130 from becoming the conductor due to the hydrogen, thereby minimizing the high brightness defects such as the strong bright spots and abnormal light emission and improving the reliability of the display device 400. According to embodiments of the disclosure, the hydrogen blocking layers disposed in planarization layers block hydrogen from flowing into transistors in the display area. A contact hole connects the hydrogen blocking layers disposed in different planarization layers and the combined structure can completely cover side surfaces of planarization layers. Additionally, having multiple contact holes between the hydrogen blocking layers can further enhance the ability to block the hydrogen inflow when one of the contact holes is detached due to any impact.

The example embodiments of the present disclosure can also be described as follows:

According to an aspect of the present disclosure, a display device includes a substrate including a non-display area including a through hole and a display area surrounding the non-display area, a dam surrounding the through hole, a first hydrogen blocking layer surrounding the dam, a first planarization layer on the first hydrogen blocking layer, a second hydrogen blocking layer on the first planarization layer, a first contact hole on the first planarization layer, the second hydrogen blocking layer surrounding the dam and overlapping with at least a portion of the first hydrogen blocking layer, the first hydrogen blocking layer in contact with the second hydrogen blocking layer in the first contact hole, and the first contact hole surrounding the dam.

The number of first contact holes can be plural.

The display device can further includes a transistor disposed on the substrate, and the first hydrogen blocking layer includes same material as a source electrode or a drain electrode of the transistor.

The display device can further include a connection electrode on the first planarization layer and connected to the transistor, a second planarization layer on the first planarization layer, the second planarization layer covering the connection electrode and the second hydrogen blocking layer, a light emitting diode on the second planarization layer connected to the connection electrode, and the connection electrode and the second hydrogen blocking layer including same material.

The first hydrogen blocking layer and the second hydrogen blocking layer can include titanium (Ti).

The display device can further include a plurality of data lines between the transistor and the first and second hydrogen blocking layer, and the plurality of data lines bypass the through hole.

The first hydrogen blocking layer and the second hydrogen blocking layer can be electrically floating.

The display device can further include a second planarization layer on the first planarization layer, the second planarization layer covering the second hydrogen blocking layer, and a third hydrogen blocking layer on the second planarization layer, the third hydrogen blocking layer surrounding the dame and overlapping with at least a portion of the second hydrogen blocking layer, the second planarization layer further including a second contact hole, the second planarization layer surrounding the dam, the second hydrogen blocking layer in contact with the third hydrogen blocking layer in the second contact hole.

The number of second contact holes can be plural.

The third hydrogen blocking layer can include titanium (Ti).

The first hydrogen blocking layer, the second hydrogen blocking layer, and the third hydrogen blocking layer can be electrically floating.

The display device can further include a plurality of patterns disposed between the first hydrogen blocking layer and the dam and between the dam and the through hole, the plurality of patterns formed of the same material as and have the same shape as the first hydrogen blocking layer or the second hydrogen blocking layer.

Each of the plurality of patterns can include a first layer, a second layer on the first layer the second layer including having a bottom surface smaller than a top surface of the first layer, and a third layer on the second layer the third layer including having a bottom surface larger than a top surface of the second layer.

A width of the third hydrogen blocking layer can be longer than a width of the second hydrogen blocking layer and longer than a width of the first hydrogen blocking layer.

The number of first contact holes and the number of second contact holes are plural, and the number of second contact holes can be greater than the number of first contact holes.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate including a non-display area including a through hole and a display area surrounding the non-display area;
a dam surrounding the through hole;
a first hydrogen blocking layer surrounding the dam;
a first planarization layer disposed on the first hydrogen blocking layer;
a second hydrogen blocking layer surrounding the dam, the second hydrogen blocking layer being disposed on the first planarization layer and overlapping with at least a portion of the first hydrogen blocking layer; and
a first contact hole in the first planarization layer, the first contact hole surrounding the dam,
wherein the first hydrogen blocking layer is in contact with the second hydrogen blocking layer via the first contact hole.

2. The display device of claim 1, wherein the first contact hole includes a plurality of first contact holes.

3. The display device of claim 1, further comprising:
a transistor disposed on the substrate in the display area,
wherein the first hydrogen blocking layer includes a same material as a source electrode or a drain electrode of the transistor.

4. The display device of claim 3, further comprising:
a connection electrode disposed on the first planarization layer and connected to the transistor;
a second planarization layer disposed on the first planarization layer, the second planarization layer covering the connection electrode and the second hydrogen blocking layer; and
a light emitting diode disposed on the second planarization layer and connected to the connection electrode,
wherein the connection electrode and the second hydrogen blocking layer include a same material.

5. The display device of claim 4, wherein the first hydrogen blocking layer and the second hydrogen blocking layer include titanium (Ti).

6. The display device of claim 4, further comprising:
a plurality of data lines disposed between the transistor and the first and second hydrogen blocking layers,
wherein the plurality of data lines bypass or extend around the through hole.

7. The display device of claim 1, wherein the first hydrogen blocking layer and the second hydrogen blocking layer are electrically floated.

8. The display device of claim 1, further comprising:
a second planarization layer disposed on the first planarization layer and covering the second hydrogen blocking layer; and
a third hydrogen blocking layer disposed on the second planarization layer,
wherein the third hydrogen blocking layer surrounds the dam and overlaps with at least a portion of the second hydrogen blocking layer,
wherein the second planarization layer includes a second contact hole surrounding the dam, and
wherein the second hydrogen blocking layer is in contact with the third hydrogen blocking layer via the second contact hole.

9. The display device of claim 8, wherein the second contact hole includes a plurality of second contact holes.

10. The display device of claim 8, wherein the third hydrogen blocking layer includes titanium (Ti).

11. The display device of claim 8, wherein the first hydrogen blocking layer, the second hydrogen blocking layer, and the third hydrogen blocking layer are electrically floated.

12. The display device of claim 11, wherein a width of the third hydrogen blocking layer is longer than both of a width of the second hydrogen blocking layer and a width of the first hydrogen blocking layer.

13. The display device of claim 12, wherein the first contact hole includes a plurality of first contact holes and the second contact hole includes a plurality of second contact holes, and
wherein a number of the plurality of second contact holes is greater than a number of the plurality of first contact holes.

14. The display device of claim 1, further comprising:
a plurality of patterns disposed between the first hydrogen blocking layer and the dam and between the dam and the through hole,
wherein the plurality of patterns include a same material as the first hydrogen blocking layer or the second hydrogen blocking layer.

15. The display device of claim 14, wherein each of the plurality of patterns includes:
a first layer;
a second layer disposed on the first layer, the second layer including a bottom surface smaller than a top surface of the first layer; and
a third layer disposed on the second layer, the third layer including a bottom surface larger than a top surface of the second layer.

16. A display device, comprising:
a plurality of subpixels disposed in a display area of a substrate;
a through hole in a non-display area of the substrate;
a first hydrogen blocking layer surrounding the through hole;
a first planarization layer disposed on the first hydrogen blocking layer and covering the first hydrogen blocking layer;
a second hydrogen blocking layer disposed on the first planarization layer and surrounding the through hole;
a first contact hole in the first planarization layer and surrounding the through hole,
wherein the first hydrogen blocking layer is connected with the second hydrogen blocking layer via the first contact hole.

17. The display device of claim 16, wherein the first contact hole includes a plurality of first contact holes, and the first hydrogen blocking layer is connected with the second hydrogen blocking layer via the plurality of first contact holes.

18. The display device of claim 16, wherein the first hydrogen blocking layer and the second hydrogen blocking layer cover a side surface of the first planarization layer.

19. The display device of claim 16, further comprising:
a second planarization layer disposed on the first planarization layer and covering the second hydrogen blocking layer;
a third hydrogen blocking layer disposed on the second planarization layer and surrounding the through hole; and
a second contact hole in the second planarization layer and surrounding the through hole,
wherein the second hydrogen blocking layer connects with third hydrogen blocking layer via the second contact hole.

20. The display device of claim 19, wherein the first contact hole includes a plurality of first contact holes, and the first hydrogen blocking layer is connected with the second hydrogen blocking layer via the plurality of first contact holes, or
wherein the second contact hole includes a plurality of second contact holes, and the third hydrogen blocking layer is connected with the second hydrogen blocking layer via the plurality of second contact holes.

21. The display device of claim 19, wherein the first hydrogen blocking layer, the first contact hole and the second hydrogen blocking layer form a wall structure having a closed loop shape or a ring shape.

22. The display device of claim 19, further comprising:
a plurality of data lines disposed in the display area of the substrate,
wherein the first hydrogen blocking layer and the second hydrogen blocking layer are dummy data lines including a same material as the plurality of data lines.

23. The display device of claim 22, wherein the dummy data lines are stacked on top of each other as concentric rings around the through hole.
